(19) United States
(12) Patent Application Publication
(10) Pub. No.: US 2020/0400785 A1
(43) Pub. Date: Dec. 24, 2020

(54) LOW VOLTAGE SUB-NANOSECOND PULSED CURRENT DRIVER IC FOR HIGH-RESOLUTION LIDAR APPLICATIONS

(71) Applicant: B.G. Negev Technologies and Applications Ltd., at Ben-Gurion University, Beer Sheva (IL)

(72) Inventor: Mor Mordechai PERETZ, Lehavim (IL)

(73) Assignee: B.G. Negev Technologies and Applications Ltd., at Ben-Gurion University, Beer Sheva (IL)

(21) Appl. No.: 16/975,539

(22) PCT Filed: Feb. 25, 2019
(86) PCT No.: PCT/IL2019/050211

§ 371 Date: Aug. 25, 2020

(30) Foreign Application Priority Data
Feb. 28, 2018 (IL) 257786

(51) Int. Cl. G01S 7/484; H01S 5/042; G01S 17/88

(52) U.S. Cl. CPC G01S 7/484; G01S 17/88; H01S 5/0428

(57) ABSTRACT

A low voltage sub-nanosecond pulsed current driver for driving current to a load, which comprises a regulated current source connected to the load, for driving controlled current to the load (which may be a laser diode for LIDAR applications); a current routing network, being connected in parallel to the load following the regulated current source and consisting of a plurality of controlled power switches; and a controller for individually timing the operation of the plurality of controlled power switches, to generate a current pulse having desired narrow pulse width and reduced rise and fall times that will be delivered to the load.

### FIELD OF THE INVENTION

The present invention relates to the field of electronic integrated circuits. More particularly, the invention relates to a current driver integrated-circuit for high-resolution Light Detection and Ranging (LIDAR) applications.

### BACKGROUND OF THE INVENTION

Late boosts in development of autonomous vehicles, Unmanned Aerial Vehicles (UAV)s such as drones and industrial robots create a huge demand for a short-range environment-sensing interface. FIG. 1A (prior art) schematically illustrates a conceptual block diagram of a Light Detection And Ranging (LIDAR) system 101 that employs an infrared laser for distance measurement. LIDAR systems are a promising method to be cost-effective, precise and reliable for mobile applications. Range accuracy and resolution of a LIDAR depend upon the rise-time and pulse-width of emitted light pulse, which in turn is a direct function of the current supplied to the laser diode by the driver 102. Implementation of a driver with rise-time and pulse width that are less than a nanosecond poses an extreme challenge due to intrinsic parasitic capacitances and inductances of components. An ideal setup to drive a laser diode is a current source that generates short pulses with controllable pulse amplitude, width, and rise and fall times, is shown in FIG. 1B (prior art). In practice however, parasitic components limit the above parameters to a certain boundary, and perhaps more challenging is the relatively slow dynamic performance of high-impedance sources. As a result, the practical implementations of driving low-impedance loads are forced to compromise on some of the above parameters.

Some prior art methods of driving a laser diode utilize a Bipolar Junction Transistor (BJT) avalanche phenomenon. While these methods potentially result in fast rise times and short pulse width, it requires a number of transistor stages to improve the rise time in every subsequent transistors stage. It is also requires extremely high voltages, on the order of hundreds and even thousand volts to generate an avalanche. Pulse shaping is complex and the efficiency of these methods is rather low, resulting in bulky and excessive heat generating installations, with low Pulse Repetition Frequency (PRF) located within kilohertz scale.

An alternative and simpler approach to drive a laser diode is to charge a capacitor to a predefined voltage, and then activate a switch that discharges the capacitor to the laser diode to generate a light pulse. This approach too requires a relatively high voltage, since the current is developed according to the impedance of the laser diode. The most significant drawback of this method is that switching device/s with extremely short transition and delay times are required.

Furthermore, both of the abovementioned methods require a special technology for integrated circuit implementation such as an expensive avalanche BJT or a gallium nitride (GaN) device with proper drive.

It is an object of the present invention to provide a high and rapid current-sourcing power driver for LIDAR applications that overcomes the drawbacks of the prior art.

Other objects and advantages of the invention will become apparent as the description proceeds.

### SUMMARY OF THE INVENTION

The present invention is directed to a low voltage sub-nanosecond pulsed current driver for driving current to a load, which comprises:
a. a regulated current source connected to the load, for driving controlled current to the load (which may be a laser diode for LIDAR applications);
b. a current routing network, being connected in parallel to the load following the regulated current source and consisting of a plurality of controlled power switches; and
c. a controller for individually timing the operation of the plurality of controlled power switches, to generate a current pulse having desired narrow pulse width and reduced rise and fall times that will be delivered to the load.

The current driver may further comprise:
a. an inductor for creating a high impedance path, to force current to flow into the load;
b. a half-bridge synchronous rectifier current source, consisting of a pMOS high-side switch and an nMOS low-side switch, providing current to the inductor.
The half-bridge synchronous rectifier current source may consist of two nMOS switches, each having different drive circuit.

The current driver may further comprise:
a. a monolithic clamping diode for preventing overvoltage of the current routing network;
b. a current sensor for sensing the current provided to the current routing network;
c. a comparator for comparing the sensed current to a reference current; and
d. a controller receiving the comparator's result and accordingly controlling switching of the current routing network.

The current routing network may comprise three MOSFET power switches, two of which are arranged in parallel to each other and to the load, and the third of which is arrange in series to the load.

The timing sequence provided by the controller may be repeated periodically, on demand.

An additional power transistor may be further connected in series with the load, such that when the additional power transistor is turned off, the impedance of the load path is increased and the current flow via the load is rapidly halted, to thereby reduce turn off delays introduced by stray inductances.

The power switches may be high-voltage 5V-gated LDMOS-2 power transistors having a gate width of 15, 000 μm.

The current sensor may comprise:
i. a matched senseFEET LDMOS switch M_{SFET};
ii. a trans-impedance amplifier;
iii. a current mirror; and
iv. an on-chip poly based resistor through which the sensed current flows;

The comparator may comprise:
i) a differential pMOS pair that is biased for amplifying voltage differences at the comparator input;
ii) differential nMOS pair that is biased to amplify the comparator input;
iii) a reference current input;
iv) a positive resistive feedback network comprising feedback resistors that are provided in a hysteresis arrangement to improve noise-immunity at the input of the comparator; and
v) an output stage comprising a plurality of cascaded inverters to generate a rail-to-rail output;

The comparator may further comprise active load current mirror structures and bias currents.

The current driver may further comprise an external clamping voltage rail to which the monolithic clamping diode is connected, for providing an additional low impedance path.

The current sensor may be implemented solely by standard CMOS devices.

The comparator may further comprise isolating rings for increasing noise-immunity of the differential pMOS and nMOS pairs.

The low voltage sub-nanosecond pulsed current driver may be implemented on an integrated circuit (IC).

The load may also be a laser diode configured to emit a light pulse proportional to the current supplied thereto.

The constant current source may be switched to lower amplitude, or completely turned off, depending on the PRF and the desired duty cycle of the load.

The switching frequency of the rectifier may be selected to be sufficiently slower than the width of the load pulse, so that the current source is virtually constant to the pulse generation switches.

### BRIEF DESCRIPTION OF THE DRAWINGS

In the drawings:

FIG. 1A schematically illustrates a conceptual system block diagram of a Light Detection and Ranging (LIDAR) system;

FIG. 1B shows an idealized current driving concept;

FIG. 2A shows a current driving conceptual circuit, according to an embodiment of the present invention;

FIG. 2B illustrates an idealized gating sequence and load current of the conceptual circuit of FIG. 2A;

FIG. 3A schematically illustrates simulation schematics of a current drive according to an embodiment of the present invention;

FIG. 3B shows simulation waveforms of the current drive of FIG. 3A;

FIG. 4 shows a block diagram of a low voltage sub-nanosecond pulsed current driver integrated circuit, according to an embodiment of the present invention;

FIG. 5 schematically illustrates a current sensing circuit, according to an embodiment of the present invention;

FIG. 6 schematically illustrates a rail-to-rail comparator, according to an embodiment of the present invention;

FIG. 7 shows a chip layout of a low voltage sub-nanosecond pulsed current driver IC, according to an embodiment of the present invention;

FIG. 8 shows a micrograph of a packaged die of three different LDMOS devices according to an embodiment of the present invention;

FIGS. 9A-9B present LDMOS-2 slew rate and stable avalanche voltage measurements;

FIG. 10 shows a laser diode modeled with forward biasing of 2V including key parasitic elements, according to an embodiment of the invention;

FIGS. 11A-11B show post-layout results of the layout of FIG. 7; and

FIG. 12A-12B show experimental measurements of photodiode output voltage, light output, and anode voltage of the laser diode of FIG. 10.

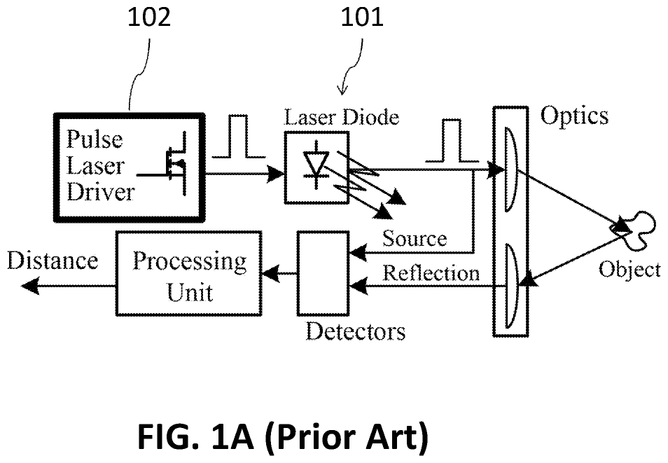

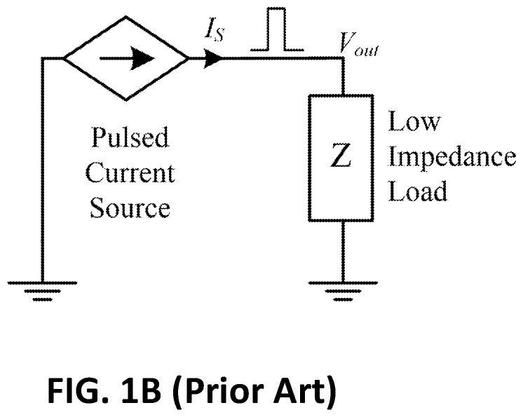

### DETAILED DESCRIPTION OF THE INVENTION

Reference will now be made to embodiments of the present invention, examples of which are provided in the accompanying figures for purposes of illustration only. One skilled in the art will readily recognize from the following description that alternative embodiments of the structures and methods exemplified herein may be employed, mutatis mutandis, without departing from the principles of the invention.

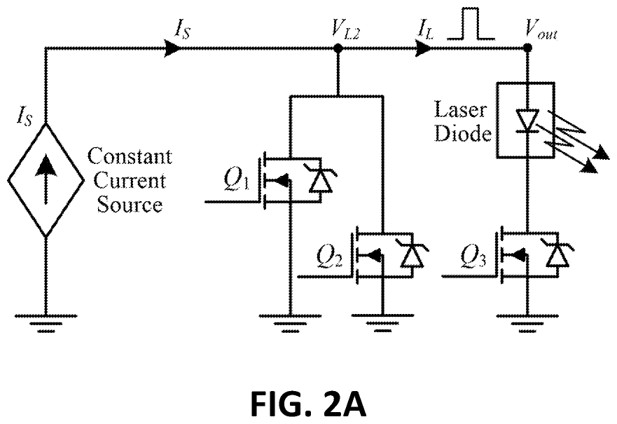

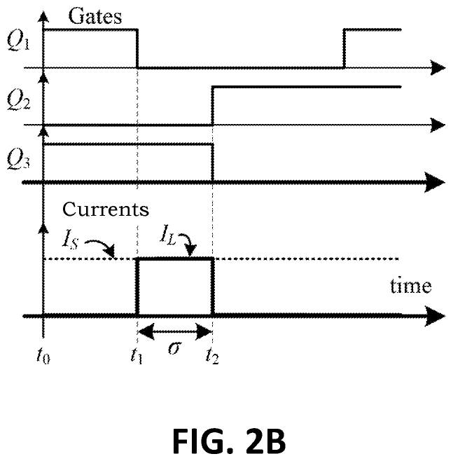

FIG. 2A shows a current driving concept, according to an embodiment of the present invention, utilizing a regulated constant current source 201 followed by a network of power switches, Q1, Q2 and Q3 that cooperatively act as a current routing network. The operation of the driver is described in FIG. 2B that illustrates an idealized gating sequence and load current. The operation is divided into an idle state and two phases: turning on and turning off transitions. In the idle state to, the switch Q1 is on, providing a closed path for the current flow of the source, while the switches Q2 and Q3 are turned off. At this point, the system is ready for outputting a current pulse. In the turn on phase t1, Q3 is on and Q1 turns off. Consequently, the current from the source is routed towards the load, laser diode in this case. The turn off phase t2 is commenced by simultaneously turning Q2 on and Q3 off, thereby causing the inductor current to rapidly route back off the load through Q2.

The use of the additional parallel transistor Q2, as opposed to operation with Q1 alone, allows flexible setting of the pulse duration with precise and high time resolution, which cannot be obtained using a single device, due to the relatively long intrinsic delays and response time that are involved with high current devices. The series transistor Q3, when turned off, increases the impedance of the load path so that the current flow is rapidly halted. As will be detailed below, it also assists to overcome the effect of stray inductances that in the practical case, introduces significant turn off delays.

It should be noted that the gating sequence described above (with relation to FIG. 2B) can be repeated periodically, on demand. For energy saving purposes, between sequence cycles, and depending on the PRF and the desired duty cycle of the load, the constant current source may be switched to lower amplitude, or completely turned off.

As it is an object of the present invention to provide a power driver that is able to supply high-resolution pulse width adjustment, ultra-fast rise and fall times, controllable current amplitude, and it is compatible for IC implementation, there are several challenges associated with the objectives above.

### Time Delays of Practical Components

The current routing switches are power MOSFETs with unavoidable intrinsic delay between turn on command and the conduction of the MOSFET channel, td(on). In particular, for power devices that are designed to handle significant current ratings, these delays are on the order of several nanoseconds to some tens of nanoseconds. To achieve time resolution of some hundreds of picoseconds for the pulse width setting, a Vernier method (a time measuring technique) is employed. Two MOSFETs, Q1 and Q2 (FIG. 2A), are placed in parallel to each other. One transistor is designed and rated for high current whereas the second transistor is designed for speed and can be of smaller size for die optimization.

Prior to the turn on phase, MOSFET Q2 is turned off, while MOSFET Q1 is left on. At the point t1 (FIG. 2B) two gate commands (that are offset from one another by the width of the pulse σ) are generated, turning Q1 off, and with delay of σ at time t2, turning Q2 on. As a result, this Vernier time-skewed command of Q1 and Q2, reroutes the current from the source to the load for a seconds, enabling to achieve a pulse width that is significantly faster than the intrinsic delay of the device's td(on).

### Parasitic Capacitances

MOSFET switch Q1 is the main path for high constant current generated by the current source. To attain high efficiency, the on state resistance of the switch, R_{ds,on}, needs to be as small as possible. According to an embodiment of the present invention, a large MOSFET with low R_{ds,on} is used. However, this comes at the cost of higher drain-source (output) capacitance of the device, CDS. This capacitance imposes finite slew-rate of the voltage build up across the load, which in turn limits the rise time of the current due to stray inductances in series with the load. To achieve high voltage slew-rates, high currents are required from the source. In addition to limiting the slew-rate, the parasitic capacitance CDS resonates with parasitic inductance of the load path, setting up the limit for rise time.

To address these challenges, a current driver according to the present invention is implemented on an integrated circuit design. Adjustable design of the power device, and miniaturization of the whole circuit, i.e. on-chip implementation, allows achieving several goals. Reduction of the parasitic components in the current path, i.e. lower CDS and lower parasitic inductances due to the on-chip interconnections. A better balance between on-resistance and switch output capacitance according to the output requirements and integration of the gate driver with the power switches (Q1-Q3) to facilitate higher driving speeds are achieved.

### Parasitic and Stray Inductances

Fall time of the current pulse through the laser diode depends on the parasitic inductances and the voltage that is applied to the laser diode during its turn off. In conventional current driving methods, a freewheeling diode (a diode connected across an inductor used to eliminate sudden voltage spike seen across an inductive load when its supply current is suddenly reduced or interrupted) is added in parallel to the load to avoid high voltage damage as a result of the residual energy in the stray inductance. However, since the forward voltage of laser diodes is relatively low, if freewheeling is allowed, the turn off time extends and cannot be regulated. It should also be noted that during the turn off period, the current ‘tail’ circulates energy through the load path, which is an undesirable scenario for LIDAR applications.

To overcome this challenge, an additional switch Q3 in the load path is employed. Switch Q3 turns off together with the turn on of Q2 so that any residual current in load path charges the output capacitance of Q3, which in turn boosts the voltage at the drain of Q3. Increased voltage at the drain of Q3 creates a high negative voltage across the parasitic inductance, resulting in rapid turn off time of the load.

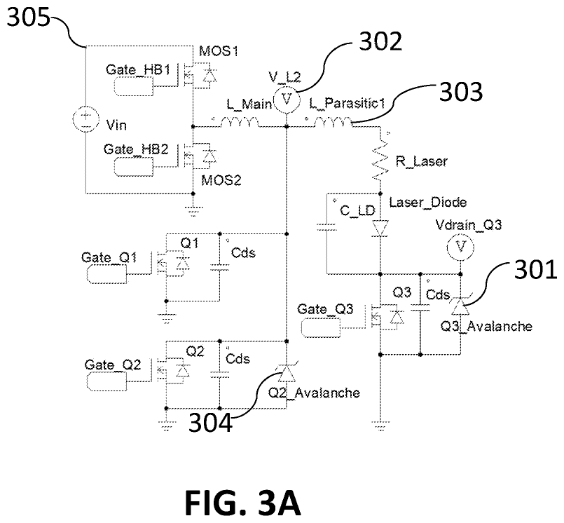

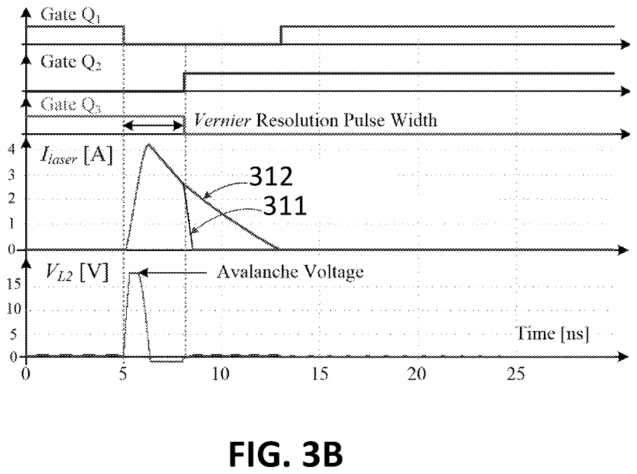

FIG. 3A schematically illustrates simulation schematics of a current drive according to an embodiment of the present invention. High voltages at the drain of Q3 could potentially damage the laser diode. To protect the laser diode from very high reverse voltages, switch Q3 has reasonable avalanche voltage level, so that at very high currents the voltage is clamped to some maximum value by the MOSFET (symbolically represented in FIG. 3A by numeral 301).

Additional effects of parasitic inductances in the presence of current source are instantaneous voltage spikes at the switching nodes. In this circuit, the node prone to this problem is VL2 (numeral 302 in FIG. 3a), where L_{Parasitic1}, 303, avoids an immediate current redirection to the laser diode. The voltage at node 302 rises as a function of current amplitude and the total node capacitance, and can reach very high values compromising the power switches Q1 and Q12.

One way to overcome this challenge is to add an auxiliary Zener diode. This solution however, adds extra parasitic capacitance and in terms of monolithic implementation and requires large silicon area. This problem is addressed, according to the present invention, on a solution based on avalanche rated integrated MOSFETs, which is symbolically represented as numeral 304 in FIG. 3.

FIG. 3B shows simulation waveforms of the current drive of FIG. 3A. Vernier method is employed in the simulation, to generate high-resolution pulse width of the laser current, Iₗₐₛₑᵣ. In addition, the voltage at node 302 is clamped to the avalanche breakdown voltage, which is predefined in the simulation to 18V, and simulated by a Q2_Avalanche device (see FIG. 3A). An example of fall time improvement over the conventional case without the additional switch Q3 is given in the middle plot of FIG. 3B. The fall time (graph 311) of the system according to the present invention is much shorter than the fall time of the conventional freewheeling approach (graph 312).

### Controlled Current Source

According to an embodiment of the present invention, the controlled current source is implemented by a half-bridge synchronous rectifier 305 that feeds an inductance to create high output impedance, as shown in FIG. 3A. The series inductance satisfies the high impedance characteristics of the sourcing element. To assure virtually constant current delivery the inductance value is set sufficiently high so that the per-pulse energy that is delivered through the inductor results in a negligibly small discharge, i.e. LI²>E_{delivered}. The switching frequency of the rectifier is selected to be sufficiently slower than the width of the load pulse, so that the current source is virtually constant to the pulse generation switches. To successfully control the half-bridge based current source 305, accurate current sensing over wide range is required, that is implemented on-chip.

### IC Implementation

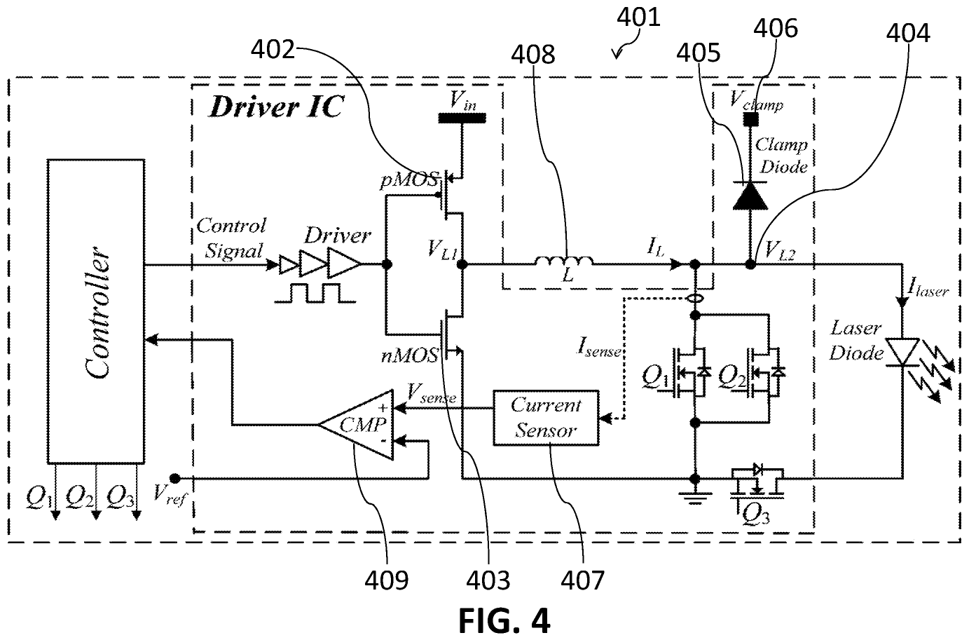

FIG. 4 is a block diagram of a low voltage sub-nanosecond pulsed current driver integrated circuit (IC) 401, according to an embodiment of the present invention. IC implemented driver 401 integrates power, analog and digital logic on one die. Layout constraints such as adding guard rings and isolation wells between the devices are employed to reduce coupling noise and undesired holes/electrons injection. An extra care is taken to the layout of the high current routes. On one hand, wide metal routes potentially result in electromigration (the transport of material caused by the gradual movement of the ions in a conductor due to the momentum transfer between conducting electrons and diffusing metal atoms), while on the other hand low width metal routes contribute to parasitic resistance. This is addressed by keeping the high current routes as short as possible to minimize redundant metallization resistance.

Current driver IC 401 comprises a current source and current routing power MOSFETs (Q1, Q2 and Q3); a synchronous rectifier includes a pMOS high-side switch 402 and an nMOS low-side switch 403; a monolithic clamping diode 405; a current sensor 407; and inductor 408; and a rail-to-rail comparator 409, each of which are explain in detail hereinbelow.

A unique feature of IC implemented driver 401 is the low voltage operation, Vᵢₙ=5V, while being capable of providing high amplitude current pulses to the load at high PRF. Since the size factor of the design is a valuable merit as well, the half-bridge power-stage is realized by standard 5V CMOS devices. As shown in FIG. 4, the synchronous rectifier includes a pMOS high-side switch 402 and an nMOS low-side switch 403 that are designed, according to an embodiment of the present invention, symmetrically with silicon on-resistance of 50 mΩ (while neglecting the parasitic resistances caused by the metallization and bond wires). The effective gate widths of switches 402 and 403 are W_{g,pMOS}=152,000 μm and W_{g,nMOS}=52,800 μm. Realizing the high-side switch by a standard pMOS device enables a ground-referenced gating signal for the half-bridge 305 (with gate voltage swing between 0 to 5V), i.e. neither level shifter nor isolation are required. The latter also implies that the driving stage of the synchronous rectifier can be simplified to a single cascaded buffers chain, conserving both the die-area and power consumption.

The drain voltage 404 of the switches Q₁ and Q₂ can potentially rise over the rated breakdown voltage of the standard 5V CMOS devices. To guarantee the reliability in terms of overvoltage protection of a high performance power system on-chip, high breakdown voltage Laterally Diffused MOS (LDMOS) power devices are used. According to an embodiment of the present invention, transistors Q₁, Q₂ and Q₃ are implemented symmetrically by a high-voltage 5V-gated nLDMOS power device having a gate width of 15,000 μm.

Another issue associated with power switches is voltage clamping, which is achieved using an avalanche breakdown effect of the LDMOS. A batch of three types of LDMOS transistors with different doping levels and oxide thickness have been fabricated and examined through a life-cycle test. The test forces avalanche conditions with various energy levels, at repetition rates of 1 MHz over four weeks per device. It has been found that in case that the energy levels applied per avalanche do not exceed the safe operating area of the transistor, the device operates under breakdown conditions, without any reliability issues such as drifts, or other oxide memory effects.

To avoid any additional failure risks of the IC implemented driver 401 due to overvoltage at node 404, and to promote IC compatibility for gate drive application, a monolithic clamping diode 405 rated up to 40V is provided. According to an embodiment of the invention, the diode is connected to an external clamping voltage rail (a voltage “rail” refers to a single voltage provided by the power supply unit) 406, thereby providing an additional low impedance path, if needed.

A fully monolithic sub-nanosecond-pulsed current driver design is allowed mainly due to high-performance current sensing. The sensor is required to provide a relatively accurate reading of the current swing from tens milliamps to several amperes, under the frequency range of several MHz.

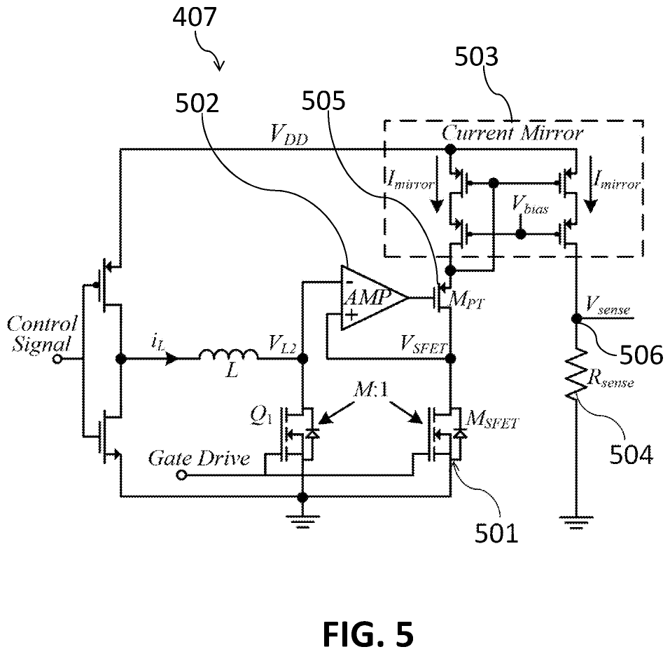

FIG. 5 schematically illustrates a current sensing circuit, according to an embodiment of the present invention. The current sensing circuit 407 is based on a senseFET approach, providing a relatively accurate sensing, while maintaining reasonable power consumption. The current sensor is realized by a matched senseFET LDMOS switch M_{SFET} 501, with a significantly smaller size than that of the main switch Q₁. To achieve accurate sensing, equal current densities between the switches are required and assured by equating the operating points of both Q₁ and M_{SFET} 501. This implies that the same gate drive signal is provided to both Q₁ and M_{SFET} 501. A trans-impedance amplifier structure 502 is used to force the same voltage drop at nodes V_{L2} and V_{SFET}. These conditions result in mirroring of the inductor current I_{L} to the M_{SFET} 501 with a ratio of “M” as depicted in Eq. 1:

Iₘᵢᵣᵣₒᵣ=I_{L}R_{on,Q}_{₁}/R_{on,M}_{_{SFET}}=I_{L}/M Eq. 1

Given the ratio of M:1 between Q₁ and M_{SFET} 501, current mirror 503's current, Iₘᵢᵣᵣₒᵣ is M times smaller than the actual inductor current I_{L}. To convert current Iₘᵢᵣᵣₒᵣ to a voltage suitable for the controller operation, current Iₘᵢᵣᵣₒᵣ is mirrored again to the output of the sensor, and flows through an on-chip poly based resistor Rₛₑₙₛₑ, 504. As a result, the voltage Vₛₑₙₛₑ across Rₛₑₙₛₑ is proportional to inductor current I_{L}. Sensing signal Vₛₑₙₛₑ is expressed, as shown in Eq. 2:

Vₛₑₙₛₑ=IₘᵢᵣᵣₒᵣRₛₑₙₛₑ=I_{L}Rₛₑₙₛₑ/M Eq. 2

It should be noted that although Q₁ and M_{SFET} 501 are implemented by LDMOS power devices, according to an embodiment of the present invention, sensing circuit 407 is implemented by standard CMOS devices only, resulting in better overall size and power consumption. The current mirror is in cascode configuration to increase the output resistance reducing the systematic mismatches. Additionally, current mirror 503's structure and transistor M_{PT} (505) are properly sized and matched to guarantee that a sufficient current can be pulled down, such that the amplifier 502 will be able to force the voltages at nodes V_{L2} and V_{SFET} to be equal.

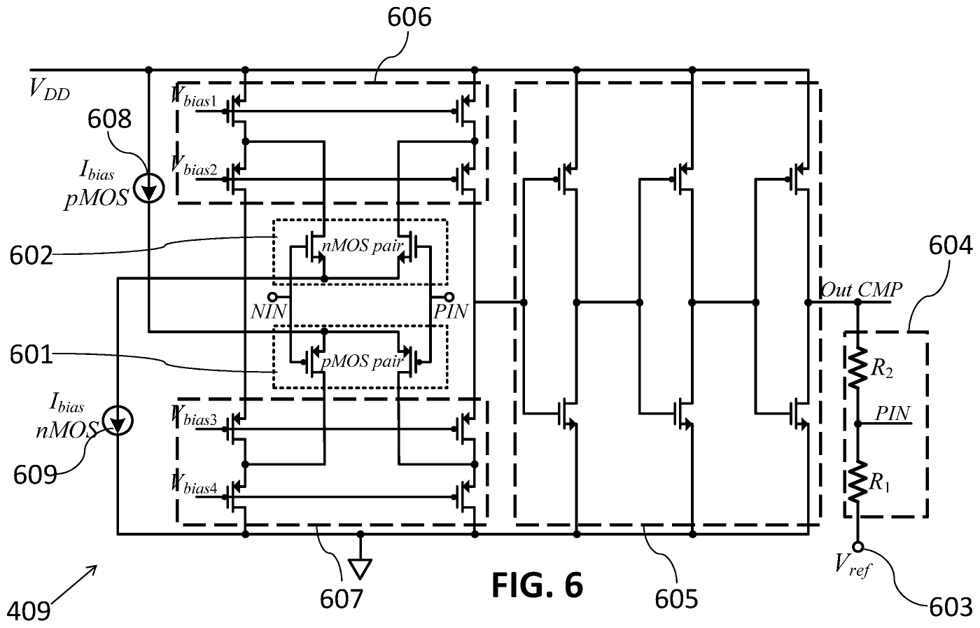

Referring once again to FIG. 4, one method of setting the current control is hysteretic-type, reference-based control scheme. Inductor 408's current is compared to a reference level, thereby triggering the operation of the half-bridge power-stage each time a reference level is crossed. Since the driver IC operates from the range of several milliamps to several amperes, a rail-to-rail comparator 409, schematically illustrated in FIG. 6, is able to operate at full swing at the input as well as at the output is used.

Complementary p-channel and n-channel differential pairs are used at the input stage to accommodate a rail-to-rail operation (a “rail” is a boundary that a signal has to work within). For low input voltages, the differential pMOS pair 601 is biased, amplifying the voltage difference at the input nodes (NIN and PIN). In a complementary manner for high input voltages the differential nMOS pair 602 is biased to amplify the input.

Comparator 409's negative input NIN is connected to the sensed signal Vₛₑₙₛₑ (506 in FIG. 5), where the positive input, PIN, is connected to a reference voltage V_{ref} 603 through a positive resistive feedback network 604. Feedback resistors R₂ and R₁ are provided in a hysteresis arrangement to improve the noise-immunity at the input of the comparator. According to an embodiment of the invention, the hysteresis band is 60 mV, whereas R₂ and R₁ are 836Ω and 68 kΩ, respectively. The output stage 605 consists of three cascaded inverters to generate a rail-to-rail output.

In a post layout experiment that was performed, measurements of the comparator resulted in total current consumption of 750 μA from the 5V supply voltage, at an operating frequency of 2.5 MHz. The propagation delay of the comparator was measured to be 8 ns for a slew rate of 2.7V/μs.

To guarantee high matching of both differential pairs for process, voltage and temperature variations, the input pairs 601 and 602 are addressed in the layout stage by using common-centroid technique. Active load current mirror structures 606 and 607 and bias currents 608 and 609 are implemented using inter digitation technique to guarantee proper matching between the transistors. According to an embodiment of the invention, isolating guard rings are added to further increase the noise-immunity of the differential pairs.

### Experimental and Post-Layout Verification

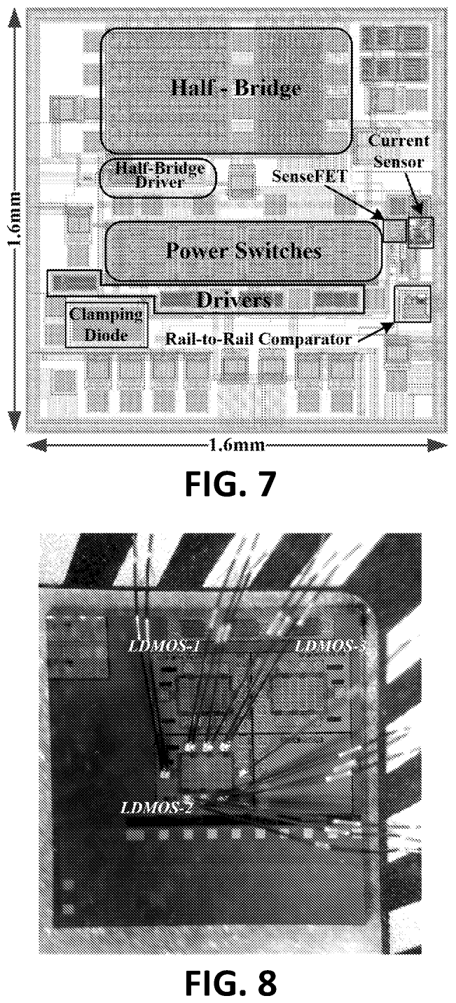

A low voltage sub-nanosecond pulsed current driver IC has been designed and fabricated in TS 0.18 μm 5V-gated power management process. The overall die area is 2.56 mm², the chip layout is shown in FIG. 7. In addition, as mentioned hereinabove, three different LDMOS devices have been custom designed and fabricated for avalanche breakdown evaluation. Micrograph of the packaged die is shown in FIG. 8.

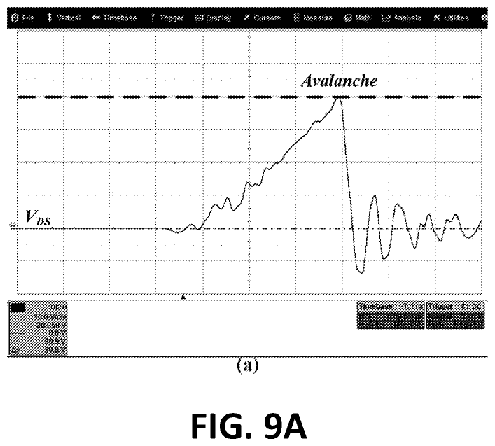

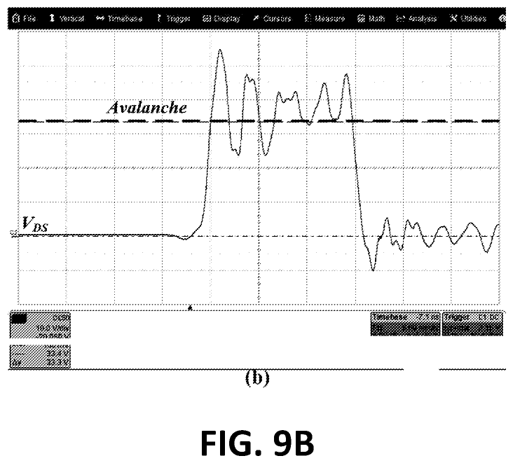

The first step of the experimental validation is to characterize the avalanche ratings of the fabricated LDMOS devices. An experimental life-cycle test that extended to four weeks per device was carried out by feeding the devices with a constant current source, while applying short turn off pulses repeated at 1 MHz. The clamped voltage of the devices was measured continuously to monitor any potential degradation of performance. During this experiment, different current amplitudes were applied to validate the change of the drain-to-source voltage, V_{DS}, rise time. In terms of slew rate and stable avalanche voltage, the best performance including extreme current cases has been achieved for LDMOS-2, as presented in FIGS. 9A and 9B. There, an average avalanche rating of approximately 36V was measured, for minimum current of 130 mA (FIG. 9A) and maximum current of 1.5 A (FIG. 9B). The results of the measured slew rates for LDMOS-2 as a function of the different currents are summarized in Table 1.

TABLE 1

| Current | 130 mA | 225 mA | 400 mA | 600 mA | 800 mA | 1.5 A |
|---|---|---|---|---|---|---|
| Turn ON | 3.3 | 5.8 | 14 | 23 | 32 | 33 |
| slew rate | GV/sec | GV/sec | GV/sec | GV/sec | GV/sec | GV/sec |

It should be noted that further increase of the current did not improve the voltage slew rate. This is explained by the limitations of the gate driver and relatively large parasitic inductances in the gate-driving path, present in the experimental setup, which was built of discrete components. According to the obtained results of the different LDMOS devices, a new generation of custom designed LDMOS has been constructed in the driver IC prototype, to attain an avalanche voltage of 18V.

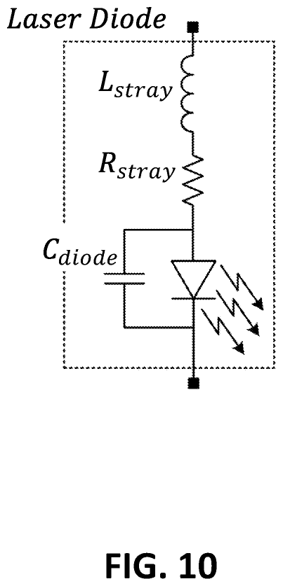

The driver IC was verified with post-layout results using Cadence Spectre simulator, demonstrating a closed-loop operation of the driver architecture. The laser diode was modeled with forward biasing of 2V including the key parasitic elements as shown in FIG. 10. The control signal for the half-bridge power-stage and gate signals for Q₁-Q₃ generating Vernier sub-resolution pulse width method are produced by a control logic block that was described, in the experiment, through Verilog-A.

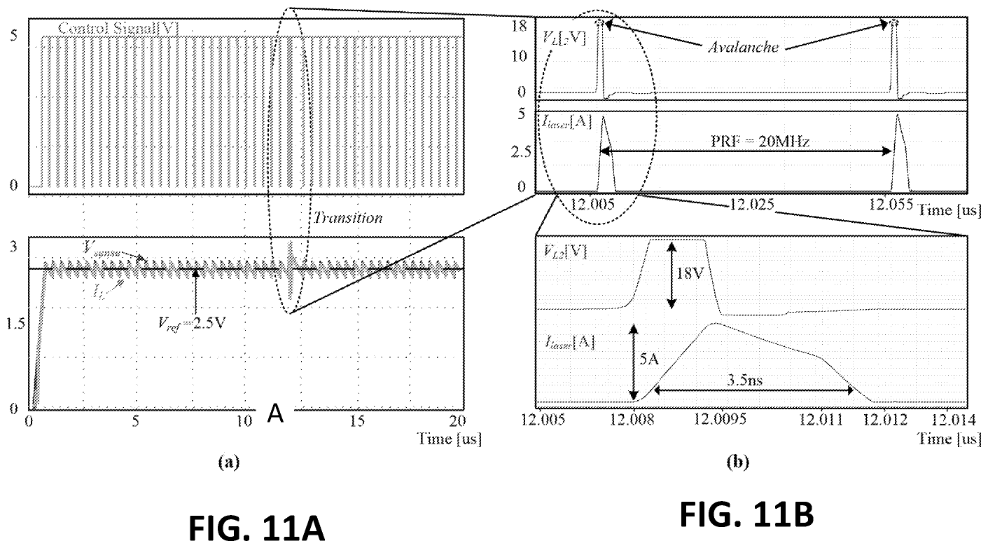

FIGS. 11A-11B shows post-layout results for a target current I_{L}=2.5 A from a 5V input, whereas the IC connects to an external inductor L=1 μH. It can be observed that at steady-state, the inductor current settles on the reference level V_{ref}=2.5V at an operating frequency of 2.5 MHz (FIG. 11A), thereby validating the proper operation of the integrated current sensor and comparator. FIG. 11B top plot shows a zoom-in on node V_{L2} and on the laser diode current Iₗₐₛₑᵣ, with a PRF of 20 MHz. FIG. 11B bottom plot is a single pulse zoom-in of the top plot, which shows the current Iₗₐₛₑᵣ with a pulse width of 3.5 ns, and rise and fall times are approximately 900 ps and 800 ps, respectively. Furthermore, the target avalanche voltage of 18V is achieved.

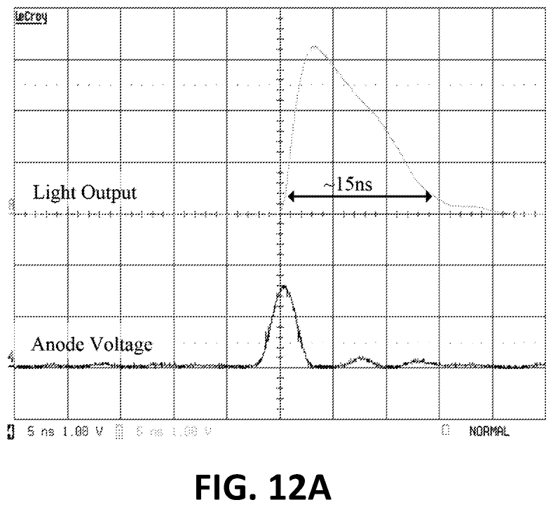

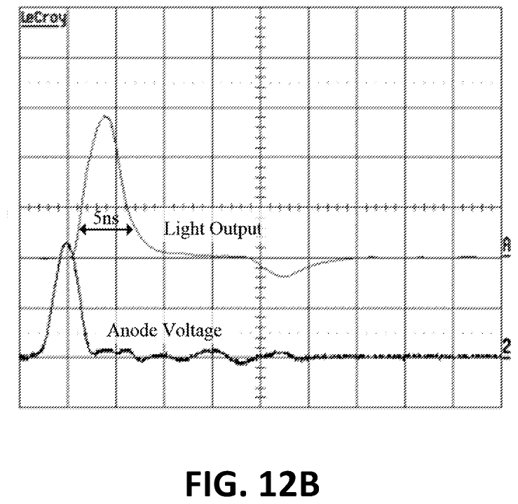

To validate the principle of operation of the driver architecture and to validate the method to shorten the fall time of the laser diode current, a discrete prototype was built and tested as part of the experiment. A constant current source is followed by a network of power switches according to FIG. 2A. A photodiode from Hamamatsu Photonics (S5972) was used as a photodetector for the experimental setup. Experimental measurements of photodiode output voltage, light output, and anode voltage of the laser diode are shown in FIGS. 12A-12B. The results without the series switch Q₃ are given in FIG. 12A, as can be seen the fall time of the current approximately 10 ns. FIG. 12B shows experimental measurements with the aid of the series switch Q₃, it can be observed that a pulse width of 5 ns is obtained, while a more noticeable benefit is that both the rise and fall times are ˜2 ns, i.e. five times shorter fall time. A small delay could be observed in the experimental results shown in FIG. 12. This delay is introduced by the optical sensor.

Although embodiments of the invention have been described by way of illustration, it will be understood that the invention may be carried out with many variations, modifications, and adaptations, without exceeding the scope of the claims.

1. A low voltage sub-nanosecond pulsed current driver for driving current to a load, comprising:
a. a regulated current source connected to said load, for driving controlled current to said load;
b. a current routing network, being connected in parallel to said load following said regulated current source and consisting of a plurality of controlled power switches; and
c. a controller for individually timing the operation of said plurality of controlled power switches, to generate a current pulse having desired narrow pulse width and reduced rise and fall times that will be delivered to said load.

2. A current driver according to claim 1, further comprising:
a. an inductor for creating a high impedance path, to force current to flow into the load; and
b. a half-bridge synchronous rectifier current source, consisting of a pMOS high-side switch and an nMOS low-side switch, providing current to said inductor.

3. A current driver according to claim 2, wherein the half-bridge synchronous rectifier current source consists of two nMOS switches, each having different drive circuit.

4. A current driver according to claim 1, further comprising:
a. a monolithic clamping diode for preventing overvoltage of the current routing network;
b. a current sensor for sensing the current provided to the current routing network;
c. a comparator for comparing the sensed current to a reference current; and
d. a controller receiving the comparator's result and accordingly controlling switching of the current routing network.

5. A current driver according to claim 1, wherein the current routing network comprises three MOSFET power switches, two of which are arranged in parallel to each other and to the load, and the third of which is arrange in series to the load.

6. A current driver according to claim 1, wherein the timing sequence provided by the controller is repeated periodically, on demand.

7. A current driver according to claim 1, wherein the load is a laser diode for LIDAR applications.

8. A current driver according to claim 1, wherein an additional power transistor is further connected in series with the load, such that when said additional power transistor is turned off, the impedance of the load path is increased and the current flow via said load is rapidly halted, to thereby reduce turn off delays introduced by stray inductances.

9. A current driver according to claim 2, wherein the power switches are high-voltage 5V-gated LDMOS-2 power transistors having a gate width of 15, 000 μm.

10. A current driver according to claim 4, wherein the current sensor comprises:
i. a matched senseFEET LDMOS switch M_{SFET};
ii. a trans-impedance amplifier;
iii. a current mirror; and
iv. an on-chip poly based resistor through which the sensed current flows.

11. A current driver according to claim 4, wherein the comparator comprises:
i) a differential pMOS pair that is biased for amplifying voltage differences at the comparator input;
ii) differential nMOS pair that is biased to amplify the comparator input;
iii) a reference current input;
iv) a positive resistive feedback network comprising feedback resistors that are provided in a hysteresis arrangement to improve noise-immunity at the input of the comparator; and
v) an output stage comprising a plurality of cascaded inverters to generate a rail-to-rail output;

12. A current driver according to claim 11, wherein the comparator further comprises active load current mirror structures and bias currents.

13. A current driver according to claim 1, further comprising an external clamping voltage rail to which the monolithic clamping diode is connected, for providing an additional low impedance path.

14. A current driver according to claim 4, wherein the current sensor is implemented solely by standard CMOS devices.

15. A current driver according to claim 10, wherein the comparator further comprises isolating rings for increasing noise-immunity of the differential pMOS and nMOS pairs.

16. A low voltage sub-nanosecond pulsed current driver according to claim 1, implemented on an integrated circuit (IC).

17. A low voltage sub-nanosecond pulsed IC implemented current driver according to claim 11, wherein the load is a laser diode configured to emit a light pulse proportional to the current supplied thereto.

18. A current driver according to claim 1, wherein the constant current source is switched to lower amplitude, or completely turned off, depending on the PRF and the desired duty cycle of the load.

19. A current driver according to claim 1, wherein the switching frequency of the rectifier is selected to be sufficiently slower than the width of the load pulse, so that the current source is virtually constant to the pulse generation switches.
